(19) United States
(12) Patent Application Publication
(10) Pub. No.: US 2026/0259288 A1
(43) Pub. Date: Sep. 3, 2026

(54) APPARATUS FOR COOLING A SUPERCONDUCTING MAGNET AND A METHOD FOR OPERATION

(71) Applicant: Siemens Healthineers AG, Forchheim (DE)

(72) Inventor: Thomas Beck, Dormitz (DE)

(21) Appl. No.: 19/553,328

(22) Filed: Feb. 28, 2026

(30) Foreign Application Priority Data
Feb. 28, 2025 (EP) 25160899

(51) Int. Cl. G01R 33/38; G01R 33/3815; G01R 33/385

(52) U.S. Cl. CPC G01R 33/3804; G01R 33/3815; G01R 33/3856

(57) ABSTRACT

A magnet control system for a superconducting field magnet of a magnetic resonance tomography system, the magnetic resonance tomography system, and a method for operation is provided. Availability of a resource for cooling the superconducting magnet is detected by the magnet control system, a first operating mode is set depending on availability, and the superconducting field magnet is cooled according to the first operating mode. No image acquisition is performed by the magnetic resonance tomography system.

This application claims the benefit of European Patent Application No. EP 25160899, filed on Feb. 28, 2025, which is hereby incorporated by reference in its entirety.

### BACKGROUND

The present embodiments relate to a magnetic resonance tomography system and a method for operating the magnetic resonance tomography system in the event of insufficient cooling resources.

Magnetic resonance tomography systems are imaging apparatuses that, in order to image an examination object, align the nuclear spins of the examination object using a strong external magnetic field and stimulate the nuclear spins to precess around this alignment using an alternating magnetic field. The precession or return of the spin from this excited state to a state with lower energy generates an alternating magnetic field in response, which is received via antennae.

With the aid of magnetic gradient fields, a spatial code is imposed on the signals, which then enables the received signal to be assigned to a volume element. The received signal is then evaluated, and a three-dimensional image of the examination object is provided. Local receiving antennae (e.g., local coils) may be used to receive the signal. These are arranged directly on the examination object to achieve a better signal-to-noise ratio.

The energy consumption of a magnetic resonance tomography system for cooling the superconducting field magnet is considerable. In addition, resources such as a heat sink for the dissipated heat are required (e.g., in the form of a cooling water circuit). If one of the resources is not available in sufficient quantity, there is a risk that the superconducting field magnet will heat up and quench.

Cooling the superconducting field magnet afterwards takes a long time, even if the field magnet has not been damaged.

Independent of the grammatical term usage, individuals with male, female or other gender identities are included within the term.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a magnet control system, a magnetic resonance tomography system, and a method for operating the magnetic resonance tomography system that allow longer bridging of a lack of resources in the cooling system are provided.

The magnet control system according to the present embodiments is intended for a superconducting field magnet of a magnetic resonance tomography system. Within the present embodiments, a magnet control system may be not only a control system in the form of a control processor, but also actuators (e.g., a cooling unit for cooling the superconducting magnet).

The magnet control system according to the present embodiments is configured to set a first operating mode and a second operating mode of the superconducting field magnet. Operating modes may be states of the magnet control system and thus of the superconducting field magnet operated by the magnet control system. For example, the operating modes are configured by sets of parameters that specify target values for sensors on the superconducting magnet. The target values are to be achieved by the actuators (e.g., the cooling unit). The operating modes may be characterized by a quasi-stationary property of the magnet (e.g., its properties such as temperature and/or magnetic field do not change or change only slightly when the magnet control system is operated with the respective set of parameters).

According to the present embodiments, the first operating mode is an operating mode with reduced cooling resource consumption. According to the present embodiments, the reduced cooling resource consumption is achieved by gradually reducing the cooling capacity of the cooling unit using the magnet control system, but without switching off the cooling unit or setting the cooling unit to zero. While the magnet control system is in the first operating mode, the superconducting property of the magnetic resonance tomography system is maintained (e.g., the temperature of the superconducting field magnet does not exceed a transition temperature).

According to the present embodiments, the second operating mode is an operating mode with improved magnetic field quality compared to the first operating mode for magnetic resonance imaging. For example, this may be a state with particularly homogenous field strength. For example, the second operating mode provides the stable operation of the superconducting magnet during image acquisition without increasing the risk of quenching due to image acquisition.

The method according to the present embodiments is intended for the operation of a magnetic resonance tomography system according to the present embodiments with a magnet control system according to the present embodiments.

The method includes the act of detecting the availability of a resource for cooling the superconducting field magnet by the magnet control system. For example, sensors that detect the temperature of the environment or the cooling water and transmit this information to the magnet control system may be provided. However, a communications interface via which the magnet control system receives information about the availability of cooling resources from the building services or external precoolers may also be provided. In the case of electrical energy, the information may also come from a sensor for voltage monitoring or a UPS, for example.

In a further act, the magnet control system sets the first operating mode depending on the availability of the resource. In one embodiment, the first operating mode is set when a cooling resource is not available or is only available to a limited extent.

Accordingly, the second operating mode may be reset by the magnet control system when the cooling resource is available to a sufficient extent. This may be determined by the magnet control system by the act for detecting availability described above.

In a further act, the superconducting field magnet is cooled according to the first operating mode. As explained hereinafter, this may be achieved by providing changed target values for controlling the cooling unit. For example, no image acquisition is performed by the magnetic resonance tomography system during cooling in the first operating mode.

In one embodiment, the first operating mode enables the superconducting state to be maintained for longer due to its reduced cooling resource consumption.

In one possible embodiment of the magnet control system, the first operating mode is configured to prevent quenching of the superconducting magnet only without magnetic resonance measurement. In other words, the operating parameters for the superconducting magnet are configured or specified so narrowly or tightly in the first operating mode that quenching may only be avoided without additional thermal load and/or magnetic load, such as that caused by gradient fields during image acquisition. The operating parameters that, for example, specify the target values for maximum temperatures and/or magnetic fields at various points on the superconducting magnet (e.g., at locations with sensors) may then be close to the theoretical limit values for the transition temperature for the static magnetic field at that location.

In one embodiment, the exclusion of additional thermal and/or magnetic loads enables superconductivity to be maintained at higher temperatures, and cooling capacity thus to be reduced.

In an embodiment of the magnet control system, the magnet control system has a cooling unit for the superconducting magnet. The cooling unit may be, for example, a pulse tube refrigerator with a compressor. The cooling unit has different adjustable power levels. For example, the cooling unit has at least one further reduced power level between a deactivated state and a permanently activated state with maximum cooling capacity. The magnet control system is configured to operate the cooling unit in the first operating mode at the reduced power level of the cooling unit, at which the cooling capacity is lower than at the maximum power level or in the permanent activated state.

In one embodiment, the cooling capacity of the cooling unit is constant or essentially constant at the reduced power level, so that the temperature of the superconducting magnet in this reduced performing state or first operating mode does not fluctuate or fluctuates by less than 0.1 K, 1 K, or 5 K, apart from a transient oscillation of the temperature when switching from another operating mode to this first operating mode. In the aforementioned pulse tube refrigerator, this may be achieved, for example, by a controllable compressor.

In one embodiment, a cooling unit with a reduced power level may be used to reduce cooling resource requirements while at the same time providing that the superconducting field magnet remains in a safe state without quenching.

In an embodiment of the magnet control system, the first operating mode specifies a first set of magnetic parameters. For example, the first operating mode may specify a temperature on a sensor on the superconducting magnet that is not to be exceeded. The temperature may also be specified depending on the magnetic field strength at the location of the sensor or another location on the superconducting magnet. In one embodiment, a pressure for a coolant (e.g., helium) that is not be exceeded may be specified. In one embodiment, the pressure depends on the temperature of the superconducting magnet.

If the magnet control system complies with the set of parameters for the first operating mode, the superconducting magnet has a predetermined thermal and/or magnetic load capacity for the superconducting magnet that is lower than in the second operating mode. Compliance with the set of parameters may be that the target values specified by the set of parameters are observed with a predetermined respective maximum permissible deviation of the sensor values from the target values. These target values indicate a state that corresponds to a lower magnetic and/or thermal load capacity of the magnet compared to the second operating mode. Target values may be specified, for example, for temperature, pressure, or magnetic field strength. In one embodiment, the parameters are dependent on the target values, such that a larger target value also corresponds to a larger parameter value; otherwise, this feature is to be applied in an equivalent manner (e.g., the parameter value for the second operating mode is correspondingly smaller). In one embodiment, the deviation of an actual value for the target value corresponding to the set of parameters is less than 0.1%, 1%, or 5%.

In a simple example, the target value may be a temperature that the superconducting field magnet is not to exceed in order to avoid quenching in the existing magnetic field generated by the superconducting current. The parameter may then be a power at which the cooling unit is to be operated in order to maintain this temperature. The parameter may be linked to this power via a function or a factor (e.g., a constant of proportionality). Indirectly, the temperature may also be specified via a gas pressure for a coolant such as helium.

Sets of parameters may be determined by calculation or experimentation and stored in the memory of the magnet control system for predetermined operating modes.

In an advantageous manner, sets of parameters may quickly specify and define different scenarios with complex physical relationships.

In one possible embodiment of the magnet control system, the second operating mode specifies or predefines a second set of parameters. In operation with the magnet control system, the second set of parameters leads to improved suitability of the magnet for imaging. That may be, for example, greater homogeneity of the magnetic field, but also improved stability of the magnetic field during image acquisition. At the same time, the set of parameters of the first operating mode is not a subset of the set of parameters for the second operating mode; in other words, a field magnet and a magnet control system that are operated in a quasi-stationary manner with the first set of parameters do not meet the conditions that a field magnet and a magnet control system meet when operated with the second set of parameters. For example, in the first operating mode there is a reduced requirement for at least one cooling resource compared to the second operating mode, while in the second operating mode, image acquisition without quenching is possible; in the first operating mode, quenching is only reliably ruled out without image acquisition. This may be achieved, for example, by operating with the second set of parameters, which leads to a lower magnet temperature, and indirectly also to a lower gas pressure of the coolant. This allows more leeway for heat and magnetic fields introduced by image acquisition, but at the same time also leads to higher consumption of cooling resources.

However, in one embodiment, although the second set of parameters leads to higher cooling resource consumption than the first set of parameters, nevertheless, it results in lower cooling resource consumption than during operation with the cooling unit permanently at maximum power.

In one embodiment, the second set of parameters allows operation with image acquisition but nevertheless has reduced requirements compared to continuous operation at maximum power and may still use the high power when there is a temporary heat input.

In an embodiment of the magnet control system, the magnet control system is configured to set the first operating mode depending on the availability of a cooling resource. For this purpose, the magnet control system may have sensors for detecting the availability of a cooling resource (e.g., a pressure or flow meter for cooling water or another secondary coolant, or a temperature sensor for detecting the temperature of the secondary coolant). Sensors for monitoring the power supply, such as, for example, a voltmeter may also be provided. A communications interface, via which the magnet control system receives information from intelligent sensors or building services or the control system of the magnetic resonance tomography system (e.g., from an uninterruptible power supply) about the network state and/or remaining capacity may also be provided.

The sensors and the interface, respectively, enable the magnet control system to respond in an independent and adaptive manner to environmental conditions without the intervention of an operator, and thus enable the longest possible uninterrupted operation (e.g., the maintenance of the magnetic field of the superconducting field magnet).

In one possible embodiment of the magnetic resonance tomography system, the magnetic resonance tomography system includes a magnet control system according to the present embodiments. The magnet control system may be configured as a separate unit, a plurality of separate units, such as, for example, a dedicated control computer and a cooling unit, or also as an integral part of the magnetic resonance tomography system. In one embodiment, for example, the control computer of the magnet control system may be the control computer of the magnetic resonance tomography system at the same time and is implemented as a program in the latter.

In one embodiment, the magnet control system and the magnetic resonance tomography system are configured to use the gradient coil as a heat sink for cooling the superconducting field magnet in the first operating mode. For example, a cooling circuit of the gradient coil may be connected to a cooling circuit of a primary cooler of the cooling unit of the magnet control system via a valve that may be switched by the magnet control, so that the magnet control system may direct warm cooling water from the primary cooler to the gradient coil and the latter is heated in this way. In one embodiment, due to the large mass, the gradient coil may serve as a heat sink for some time, provided that it has not already been heated by image acquisition (e.g., when no image acquisition is taking place which heats the gradient coil).

The properties, features, and advantages of this invention described above, and the manner in which they are achieved, will become clearer and more readily understandable in connection with the following description of the example embodiments, which are explained in more detail in connection with the drawings.

### BRIEF DESCRIPTION OF THE DRAWINGS

FIG. 1 is a diagrammatic view of an example magnetic resonance tomography system with a magnet control system according to an embodiment;

FIG. 2 is a diagrammatic view of an example magnet control system according to an embodiment;

FIG. 3 is a diagrammatic view of an example coolant circuit of an embodiment of a magnetic resonance tomography system according to an embodiment; and

FIG. 4 is a diagrammatic flow chart for a method for operating the magnetic resonance tomography system according to an embodiment.

### DETAILED DESCRIPTION

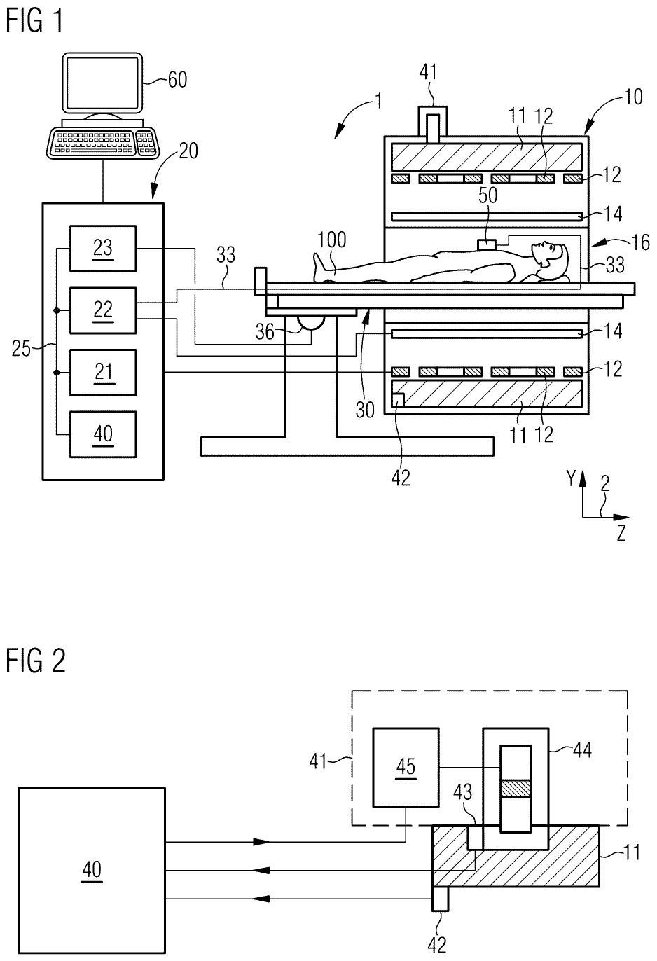

FIG. 1 shows a diagrammatic view of an embodiment of a magnetic resonance tomography system 1.

A magnet unit 10 has a field magnet 11 that generates a static magnetic field B0 for aligning nuclear spins of samples or a patient 100 in a recording area. The recording area is characterized by an extremely homogenous static magnetic field B0, the homogeneity relating, for example, to the magnetic field strength or the amount. The recording area is almost spherical and is arranged in a patient tunnel 16 that extends in a longitudinal direction 2 through the magnet unit 10. A patient couch 30 may be moved in the patient tunnel 16 by the positioning unit 36. The field magnet 11 is a superconducting field magnet that may provide magnetic fields with a magnetic flux density of up to 3T, and even higher in the latest devices.

The superconducting field magnet 11 requires a cooling unit with high power consumption and equally high waste heat, and therefore cooling requirements, in order to maintain the low temperatures of the superconducting magnetic coils.

Further, the magnet unit 10 has gradient coils 12 that are configured to superimpose temporally and spatially variable magnetic fields in three spatial directions on the magnetic field B0 in order to spatially differentiate the detected imaging areas in the examination volume. The gradient coils 12 may be coils of normal-conducting wires that may generate fields orthogonal to each other in the examination volume.

The resistive gradient coils 12 are also controlled by a gradient controller 21 with very high currents and have a corresponding demand for electrical energy and cooling requirements for the waste heat. The resistive gradient coils 12 may therefore be connected to a cooling circuit. The gradient coils 12 also have a considerable heat capacity due to their large mass.

The magnet unit 10 also has a body coil 14 that is configured to emit a radio frequency signal supplied via a signal line into the examination volume and to receive resonance signals emitted by the patient 100 and transmit the resonance signals via a signal line.

A control unit 20 supplies the magnet unit 10 with the various signals for the gradient coils 12 and the body coil 14 and evaluates the received signals.

The control unit 20 has a gradient controller 21 that is configured to supply the gradient coils 12 with variable currents via supply lines that provide the desired gradient fields in the examination volume in a temporally coordinated manner.

The magnet control system 40 of the control unit 20 controls and monitors the superconducting field magnet 11 and its cooling unit 41, respectively, using sensors (e.g., with a temperature sensor 42 on the superconducting field magnet 11 or a pressure sensor 43 that records the pressure of a coolant of the cooling unit 41 and thus indirectly also reports the temperature of the coolant and the field magnet 11 in thermal contact therewith). For example, the magnet control system 40 is configured to operate the cooling unit with at least a power level between a deactivated state and operation at maximum cooling capacity. In one embodiment, there are a plurality of operating modes with different cooling capacities or an infinitely variable cooling capacity, as is possible with compressors with an infinitely variable inverter in a cooling unit 41.

Further, the control unit 20 has a radio frequency unit 22 that is configured to generate a radio frequency pulse with a predetermined chronological sequence, amplitude, and spectral power distribution for exciting magnetic resonance of the nuclear spins in the patient 100. Pulse outputs in the kilowatt range may be achieved. The excitation signals may be radiated into the patient 100 via the body coil 14 or via a local transmitting antenna.

A device control system 23 communicates via a signal bus 25 with the gradient controller 21, the radio frequency unit 22, and the magnet control system 40.

To receive the magnetic resonance signal, a local coil 50 according to the present embodiments is arranged on the patient 100 in the patient tunnel 16 in order to detect magnetic resonance signals from an examination area in the immediate vicinity with the greatest possible signal-to-noise ratio. The local coil 50 has a signal link via a connecting line 33 to a receiver in the radio frequency unit 22.

The magnetic resonance tomography system 1 may have an interface (e.g., with a data network), via which the device control system 23 may communicate with a supply facility (e.g., send messages and receive instructions). In this manner, the device control system 23 may receive information about the availability of a cooling resource such as electrical energy, secondary cooling, or cooling water and relay the received information to the magnet control system. However, in one embodiment, the magnet control system 40 itself has such an interface (e.g., a sensor for cooling water temperature or a voltage monitor for the power supply).

FIG. 2 is a diagrammatic view of the functional relationships between the magnet control system 40, the cooling unit 41, and the sensors 42, 43 in one possible embodiment.

The magnet control system 40 controls the cooling capacity of the cooling unit 41 via the compressor 45, the output of which may be adjusted by an inverter. The compressor 45 supplies fluid under pressure to a pulse tube refrigerator 44. A reservoir of liquid helium, for example, may be located at the cold head of the pulse tube refrigerator, the pressure of which is measured with a pressure sensor 43 by the magnet control system 40. The pressure is a measure of the temperature of the reservoir and thus of elements in thermal contact with it, such as the superconducting field magnet 11. Likewise, the magnet control system 40 may directly measure the temperature of the superconducting field magnet 11 via a temperature sensor 42.

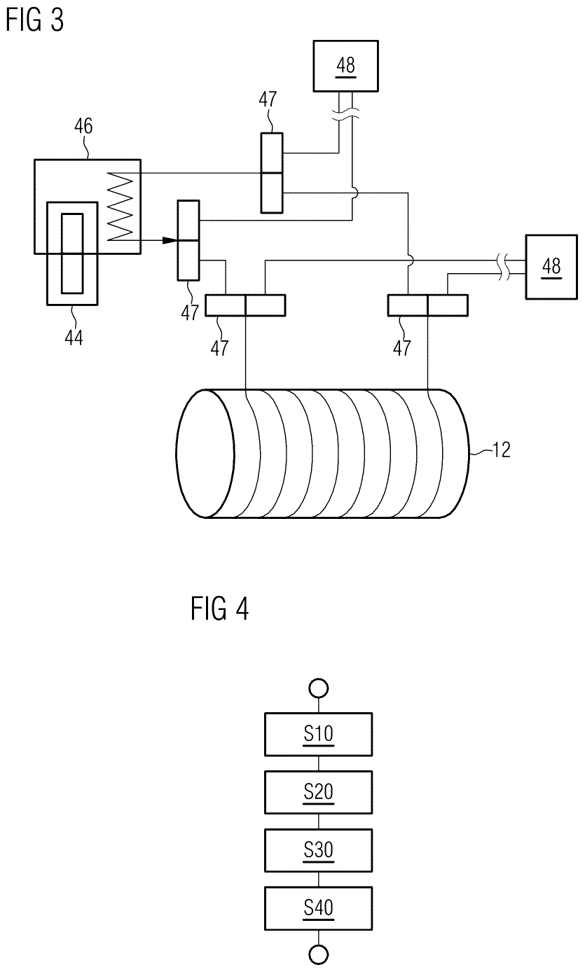

FIG. 3 shows a diagrammatic view of an example coolant circuit of an embodiment of a magnetic resonance tomography system 1.

The cooling unit 40, or in the example shown, the pulse tube refrigerator 44, is to be cooled to dissipate the heat removed from the field magnet 11, including the heat loss from the compressor 45. FIG. 3 shows the hot head of the pulse tube refrigerator 44 as a representative heat source, which transfers heat to a heat exchanger 46 in thermal contact with a coolant (e.g., cooling water). The heat is transferred from the coolant to a heat sink 48. The heat sink 48 may be, for example, a secondary cooler or a cold water source.

In one possible embodiment of the magnetic resonance tomography system 1, the magnet control system 40 or the control system 20 may connect the cooling unit to different heat sinks 48 via valves 47. For example, in the first operating mode without image acquisition, the valves 47 are set in the first operating mode such that the gradient coil 12 serves as a heat sink. As a result of the gradient currents, the gradient coil 12 generates considerable amounts of waste heat that are to be dissipated by a cooling water circuit during image acquisition. At the same time, due to the mechanical stresses, the gradient coil has a robust structure with a large mass and thus heat capacity. Using the valves 47, the coolant circuit of the cooling unit 40, shown here as the heat exchanger 46, may be connected to the cooling circuit of the gradient coil 12 such that the coolant transfers heat from the heat exchanger 46 to the gradient coil 12.

FIG. 4 shows a diagrammatic view of a flow chart for a method for operating the magnetic resonance tomography system according to the present embodiments.

In act S10 of the method, the magnetic resonance tomography system 1 detects the availability of a resource for cooling the superconducting magnet. This may be done, for example, by the device control system 23 of the magnetic resonance tomography system 1 via the interface described above. In one embodiment, a building services system or a UPS may send a message to the device control system 23 about a power failure and the limited availability of electrical energy or cooling water. However, the magnet control system 40 may also monitor availability itself via a sensor (e.g., the cooling water temperature via a temperature sensor 42). For example, the magnet control system 40 or the device control system 23 may also detect a lack of cooling resources such as electrical energy, coolant, or secondary cooling.

In a further act S20, the magnet control system 40 sets the first operating mode depending on the availability of the cooling resource. In one embodiment, this is done when information about a lack of cooling resources is available to the magnet control system 40.

The control system 23 may then no longer perform image acquisition when it itself detects the lack of cooling resources or receives the first operating mode from the magnet control system 40.

The magnet control system 40 then operates the cooling unit such that there is a reduced demand for cooling resources. To this end, the magnet control system 40 reduces the cooling capacity of the cooling unit 41 without switching it off completely for an extended period (e.g., for more than 0.01 s, 0.1 s or 1 s). In one embodiment, this results in a steady state of the cooling unit and the superconducting field magnet 11, in which the superconducting field magnet 11 has a higher temperature with a lower cooling capacity requirement than in the second operating mode, but is still cold enough not to quench the superconducting current flow. This may be achieved, for example, with a compressor equipped with an inverter for adjusting the power. In one embodiment, the magnet control system 40 actively regulates the cooling unit 41 so that a temperature of the field magnet 11 detected by a temperature sensor 42, or a pressure of the coolant detected by a pressure sensor 43, does not exceed a threshold value at which the superconducting current flow is maintained.

In one embodiment, the magnet control system 40 and/or the device control system 23 connect the coolant flow from the heat exchanger 46 to a coolant circuit of the gradient coil 12 using the valves 47, such that the gradient coil 12 serves as a heat sink for the cooling unit 41.

In act S30, the superconducting field magnet 11 is operated in the first operating mode with reduced cooling resource requirements. During cooling in the second operating mode, no image acquisition is performed by the magnetic resonance tomography system 1.

In one embodiment, in act S40, when the cooling resource is available, the magnet control system 40 sets the second operating mode again, in which image acquisition is again possible without the superconducting field magnet 11 quenching due to the additional heat input.

Although the invention has been illustrated and described in detail by the example embodiments, the invention is not limited by the disclosed examples, and other variations may be derived therefrom by a person skilled in the art without departing from the scope of protection of the invention.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A magnet control system for a superconducting field magnet of a magnetic resonance tomography system, the magnet control system comprising:
a processor configured to set a first operating mode and a second operating mode of the superconducting field magnet,
wherein the first operating mode is an operating mode with reduced cooling resource consumption, and the second operating mode is an operating mode with improved magnetic field quality for magnetic resonance imaging.

2. The magnet control system of claim 1, wherein the first operating mode is configured to prevent quenching of the superconducting field magnet only without magnetic resonance measurement.

3. The magnet control system of claim 1, further comprising a cooling unit that has at least three different adjustable power levels,
wherein the magnet control system is configured to operate the cooling unit in the first operating mode at a power level that is lower than a maximum power level.

4. The magnet control system of claim 1, wherein the first operating mode specifies a first set of magnetic parameters that, when complied with by the magnet control system, results in a predetermined thermal, magnetic, or thermal and magnetic load capacity for the superconducting field magnet that is lower than in the second operating mode.

5. The magnet control system of claim 4, wherein the second operating mode specifies a second set of parameters, and
wherein the second set of parameters, when complied with by the magnet control system, leads to improved suitability of the superconducting field magnet for imaging.

6. The magnet control system of claim 1, wherein the magnet control system is configured to set the first operating mode depending on availability of a cooling resource.

7. The magnet control system of claim 6, wherein the cooling resource is electrical energy, secondary cooling, or the electrical energy and the secondary cooling.

8. A magnetic resonance tomography system comprising:
a gradient coil; and
a magnet control system for a superconducting field magnet of the magnetic resonance tomography system, the magnet control system comprising:
a processor configured to set a first operating mode and a second operating mode of the superconducting field magnet,
wherein the first operating mode is an operating mode with reduced cooling resource consumption, and the second operating mode is an operating mode with improved magnetic field quality for magnetic resonance imaging, and
wherein the magnet control system and the magnetic resonance tomography system are configured to use the gradient coil as a heat sink for cooling the superconducting field magnet in the first operating mode.

9. A method for operating a magnetic resonance tomography system with a magnet control system for a superconducting field magnet of the magnetic resonance tomography system, the magnet control system comprising a processor configured to set a first operating mode and a second operating mode of the superconducting field magnet, wherein the first operating mode is an operating mode with reduced cooling resource consumption, and the second operating mode is an operating mode with improved magnetic field quality for magnetic resonance imaging, the method comprising:
detecting availability of a resource for cooling the superconducting field magnet by the magnet control system;
setting the first operating mode depending on the availability; and
cooling the superconducting field magnet according to the first operating mode,
wherein no image acquisition is performed by the magnetic resonance tomography system.
